(19) United States
(12) Patent Application Publication
(10) Pub. No.: US 2025/0024719 A1
(43) Pub. Date: Jan. 16, 2025

(54) DISPLAY DEVICE AND METHOD OF MANUFACTURING DISPLAY DEVICE

(71) Applicant: SAMSUNG DISPLAY CO., LTD., YONGIN-SI (KR)

(72) Inventors: Dong Hyun LEE, Yongin-si (KR); Youn Woong KANG, Yongin-si (KR); Si Joon SONG, Yongin-si (KR)

(21) Appl. No.: 18/649,240

(22) Filed: Apr. 29, 2024

(30) Foreign Application Priority Data
Jul. 11, 2023 (KR) 10-2023-0090052

(51) Int. Cl. H10K 59/131; H10K 59/12; H10K 59/124

(52) U.S. Cl. CPC H10K 59/131; H10K 59/1201; H10K 59/124

(57) ABSTRACT

A display device includes a display area and a non-display area, a first base layer and a second base layer, each including an organic material, and a barrier layer having a first surface contacting the first base layer and a second surface contacting the second base layer, and including an inorganic material. The display device further includes a light emitting element disposed on the second base layer in the display area, and a contact structure formed in the non-display area and including a conductive connection portion. An entirety of the first surface of the barrier layer contacts the first base layer.

### CROSS-REFERENCE TO RELATED APPLICATIONS

This application claims priority under 35 U.S.C. § 119 to Korean Patent Application No. 10-2023-0090052, filed on Jul. 11, 2023 in the Korean Intellectual Property Office, the disclosure of which is incorporated by reference herein in its entirety.

### TECHNICAL FIELD

Embodiments of the present disclosure relate to a display device and a method of manufacturing the display device.

### DISCUSSION OF RELATED ART

In a display device, a position of a driving chip for driving a pixel of the display device may be variously determined. For example, the driving chip may be disposed on a rear surface of the display device, and a line for electrically connecting the driving chip to the display device may be disposed in an outer area of the display device.

### SUMMARY

An object of embodiments of the present disclosure is to provide a display device in which a dead space is reduced, and a method of manufacturing the display device.

An object of embodiments of the present disclosure is to provide a display device and a method of manufacturing the display device, in which configurations in the display device is prevented from being damaged by reducing a risk that may occur during a process, and structural stability is improved.

According to an embodiment of the present disclosure, a display device includes a base layer including a first base layer including a first base hole, a second base layer including a second base hole, and a barrier layer disposed between the first base layer and the second base layer and including a barrier hole. The display device further includes a display layer including a light emitting element, a driving chip, a first conductive layer including a (1-1)-th conductive layer electrically connected to at least a portion of the display layer and a (1-2)-th conductive layer electrically connected to the driving chip, and a contact structure including a connection portion electrically connecting the (1-1)-th conductive layer and the (1-2)-th conductive layer. The first base layer includes a (1-1)-th base layer and a (1-2)-th base layer spaced apart in a thickness direction of the base layer. The second base layer includes a (2-1)-th base layer and a (2-2)-th base layer spaced apart from each other in the thickness direction. The barrier layer includes a first barrier layer and a second barrier layer spaced apart from each other in the thickness direction. The first barrier layer is disposed between the (1-1)-th base layer and the (2-1)-th base layer, and the second barrier layer is disposed between the (1-2)-th base layer and the (2-2)-th base layer. The (2-1)-th base layer forms a front surface on which the display layer and the (1-1)-th conductive layer are disposed. The (2-2)-th base layer forms a rear surface on which the driving chip and the (1-2)-th conductive layer are disposed. At least a portion of the connection portion is disposed in the first base hole. The first base hole is defined in each of the (1-1)-th base layer and the (1-2)-th base layer, and each of the (1-1)-th base layer and the (1-2)-th base layer includes a tapered surface on which the connection portion is disposed without including an under-cut structure in an area adjacent to the first base hole.

According to an embodiment, the first base layer includes a first organic material, the barrier layer includes a first inorganic material, and the second base layer includes a second organic material.

According to an embodiment, the display device further includes a first insulating layer disposed on the second base layer and including a first hole, and a second insulating layer disposed on the first insulating layer and including a second hole. Each of the first insulating layer and the second insulating layer includes a second inorganic material. The first hole, the second hole, the first base hole, and the second base hole are fluidly connected to each other.

According to an embodiment, the display layer includes a transistor electrically connected to the light emitting element and including a transistor electrode. The transistor electrode and the first conductive layer include a same material as each other.

According to an embodiment, in a plan view, a size of the second base hole and a size of the barrier hole correspond to each other.

According to an embodiment, an entirety of an upper surface of the barrier layer contacts a lower surface of the second base layer.

According to an embodiment, in a plan view, a size of the first base hole is smaller than a size of the barrier hole and a size of the second base hole.

According to an embodiment, the display device further includes an adhesive layer disposed between the (1-1)-th base layer and the (1-2)-th base layer and including an adhesion hole. The first base hole and the adhesion hole have an hourglass shape in a cross-sectional view of the display device.

According to an embodiment, the display device further includes an adhesive layer disposed between the (1-1)-th base layer and the (1-2)-th base layer and including an adhesion hole. The first base hole and the adhesion hole have a trapezoidal shape in a cross-sectional view of the display device.

According to an embodiment, the display device further includes a first insulating layer disposed on the second base layer, including a first hole, and including an inorganic material. At least a portion of the barrier layer protrudes from the second base layer in a plan view. In the plan view, the first hole and the barrier hole have sizes corresponding to each other.

According to an embodiment, in a plan view, the first base hole and the barrier hole have sizes corresponding to each other.

According to an embodiment, the first base hole includes a first area where a first portion of the first base layer is removed by an etching process and a second area where a second portion of the first base layer is removed by a laser process. In a plan view, the first area removed by the etching process is greater than the second area removed by the laser process.

According to an embodiment, the display device further includes a second conductive layer disposed on the first conductive layer. The second conductive layer is disposed on a same layer as at least a portion of a line of the display layer.

According to an embodiment, the contact structure is one of a plurality of contact structures arranged in a zigzag pattern.

According to an embodiment of the present disclosure, a display device includes a display area and a non-display area, a first base layer and a second base layer each including an organic material, and a barrier layer having a first surface contacting the first base layer and a second surface contacting the second base layer, and including an inorganic material. The display device further includes a light emitting element disposed on the second base layer in the display area, and a contact structure formed in the non-display area and including a conductive connection portion. An entirety of the first surface of the barrier layer contacts the first base layer.

According to an embodiment of the present disclosure, a method of manufacturing a display device includes manufacturing a base layer including a first base layer, a barrier layer, and a second base layer, and including a first area and a second area. A portion of the base layer in the first area overlaps another portion of the base layer in the second area. The method further includes exposing at least a portion of the first base layer in a hole formation area, and forming a first base hole passing through the first base layer in the hole formation area after exposing the at least a portion of the first base layer in the hole formation area.

According to an embodiment, the method further includes disposing a display layer in the first area on the second base layer and disposing a driving chip in the second area on the second base layer. The first base layer includes a (1-1)-th base layer disposed in the first area and a (1-2)-th base layer disposed in the second area, and the barrier layer includes a first barrier layer disposed in the first area and a second barrier layer disposed in the second area. The second base layer includes a (2-1)-th base layer disposed in the first area and a (2-2)-th base layer disposed in the second area.

According to an embodiment, the method further includes folding the base layer, and removing at least a portion of the folded base layer. Folding the base layer includes disposing the display layer on one side of the base layer in the first area and disposing the driving chip on another side of the base layer in the second area.

According to an embodiment, forming the first base hole includes removing at least a portion of the first base layer using a laser. When forming the first base hole, a layer including an inorganic material is not disposed in the hole formation area.

According to an embodiment, the laser includes a first laser and a second laser directed toward different directions.

According to an embodiment of the present disclosure, a display device in which a dead space is reduced and a method of manufacturing the display device may be provided.

According to an embodiment of the present disclosure, a display device and a method of manufacturing the display device, in which configurations in the display device is prevented from being damaged by reducing a risk that may occur during a process, and structural stability is improved may be provided.

### BRIEF DESCRIPTION OF THE DRAWINGS

The above and other features of the present disclosure will become more apparent by describing in further detail embodiments thereof with reference to the accompanying drawings, in which:

FIGS. 1 and 2 are schematic plan views illustrating a display device according to an embodiment;

FIG. 3 is a schematic cross-sectional view illustrating a display device according to an embodiment;

FIGS. 4 to 9 are schematic cross-sectional views illustrating a display device including a contact structure according to an embodiment;

FIG. 10 is a schematic plan view illustrating a first hole, a second hole, and a third hole according to an embodiment; and

FIGS. 11 to 17 are schematic cross-sectional views illustrating a method of manufacturing a display device according to an embodiment.

### DETAILED DESCRIPTION OF THE EMBODIMENTS

Embodiments of the present disclosure will be described more fully hereinafter with reference to the accompanying drawings. Like reference numerals may refer to like elements throughout the accompanying drawings.

Terms of “first”, “second”, and the like may be used to describe various components, but the components should not be limited by the terms. The terms are used only for the purpose of distinguishing one component from another component. For example, without departing from the scope of the present disclosure, a first component may be referred to as a second component, and similarly, a second component may also be referred to as a first component. In the following description, the singular expressions include plural expressions unless the context clearly indicates otherwise.

It should be understood that in the present application, a term of “include”, “have”, or the like is used to specify that there is a feature, a number, a step, an operation, a component, a part, or a combination thereof described in the specification, but does not exclude a possibility of the presence or addition of one or more other features, numbers, steps, operations, components, parts, or combinations thereof in advance. In addition, a case where a portion of a layer, an area, a plate, or the like is referred to as being “on” another portion includes not only a case where the portion is “directly on” another portion, but also a case where another portion is further disposed between the portion and the other portion. In addition, in the present specification, when a portion of a layer, an area, a plate, or the like is formed on another portion, a forming direction is not limited to an upper direction but includes forming the portion on a side surface or in a lower direction. Further, when a portion of a layer, an area, a plate, or the like is formed “under” another portion, this includes not only a case where the portion is “directly beneath” another portion, but also a case where another portion is further disposed between the portion and the other portion.

The disclosure relates to a display device and a method of manufacturing the display device. Hereinafter, a display device and a method of manufacturing the display device according to embodiments are described with reference to the accompanying drawings.

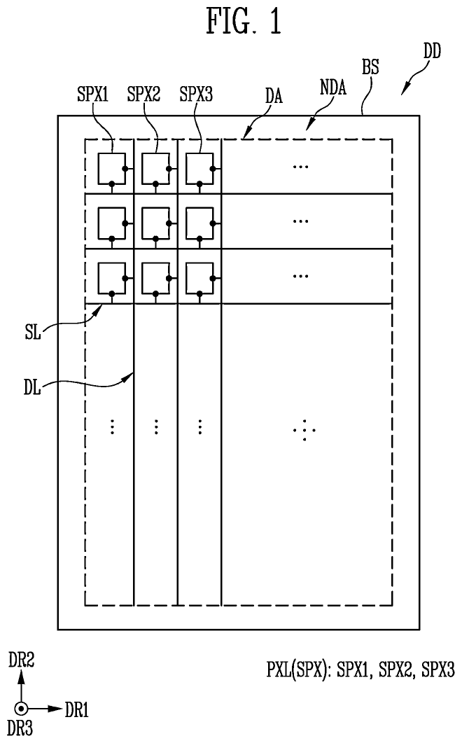

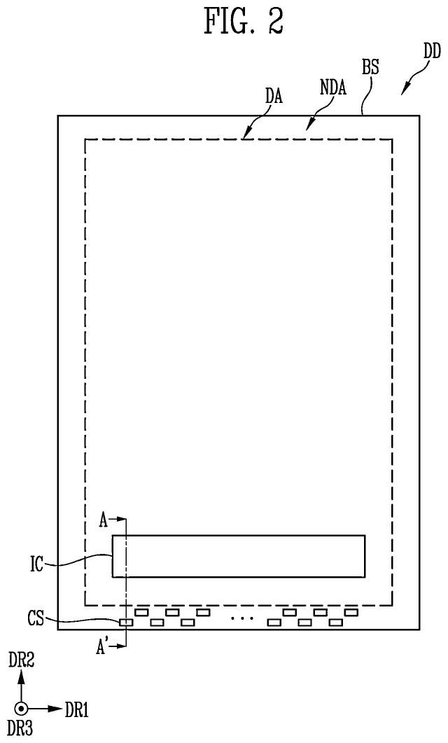

FIGS. 1 and 2 are schematic plan views illustrating a display device according to an embodiment.

Referring to FIGS. 1 and 2, the display device DD is configured to display light by including a base layer BS and a pixel PXL (or sub-pixels SPX) disposed (or formed) on the base layer BS. The display device DD may further include a driving circuit unit (for example, a driving chip IC including a scan driver and/or a data driver), scan lines SL, data lines DL, lines, and a contact structure CS for driving the pixel PXL.

The display device DD may include a display area DA in which an image may be displayed, and a non-display area NDA in which an image is not displayed. The non-display area NDA refers to an area other than the display area DA. The non-display area NDA may surround at least a portion of the display area DA. The non-display area NDA may be a dead space.

The base layer BS may form a base of the display device DD. The base layer BS may include various materials. For example, the base layer BS may include a rigid or flexible substrate or film.

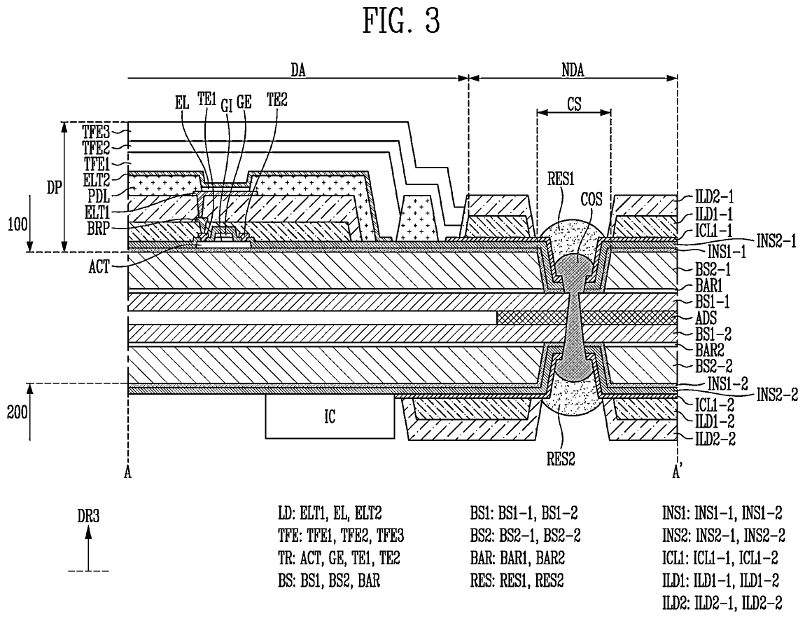

According to an embodiment, the base layer BS may include a plurality of layers. According to an embodiment, the base layer BS may have a multilayer structure in which an organic material layer, an inorganic material layer, and an organic material layer are sequentially stacked. For example, the base layer BS may include a first base layer BS1 (refer to FIG. 3) including an organic material, a barrier layer BAR (refer to FIG. 3) including an inorganic material, and a second base layer BS2 (refer to FIG. 3) including an organic material. Details regarding this are described in further detail below with reference to the drawings after FIG. 3.

The display area DA may refer to an area where the pixel PXL (or the sub-pixels SPX and light emitting elements LD (refer to FIG. 3) are disposed. The non-display area NDA may refer to an area in which the pixel PXL is not disposed.

According to an embodiment, the pixel PXL may be arranged according to various arrangement structures. For example, the pixels PXL may be arranged according to a stripe or PENTILE™ arrangement structure. However, the disclosure is not limited thereto.

According to an embodiment, the pixel PXL (or the sub-pixel SPX) may include a first sub-pixel SPX1, a second sub-pixel SPX2, and a third sub-pixel SPX3. At least one of the first sub-pixel SPX1, the second sub-pixel SPX2, and the third sub-pixel SPX3 may form one pixel unit capable of emitting light of various colors.

For example, the first sub-pixel SPX1 may be a red sub-pixel emitting red light (e.g., a first color), the second sub-pixel SPX2 may be a green sub-pixel emitting green light (e.g., a second color), and the third sub-pixel SPX3 may be a blue sub-pixel emitting blue light (e.g., a third color).

The scan lines SL may be electrically connected to the scan driver. According to an embodiment, the scan driver may be included in the driving chip IC. Scan connection lines electrically connected to the scan lines SL may be disposed in the non-display area NDA, and the scan connection lines may be electrically connected to the driving chip IC disposed on a rear surface of the base layer BS through the contact structure CS.

The scan lines SL may extend along a pixel row. For example, the scan lines SL may extend along a first direction DR1 and may be spaced apart from each other along a second direction DR2. Each of the scan lines SL may be electrically connected to a pixel circuit of each of the sub-pixels SPX.

The data lines DL may be electrically connected to the data driver. According to an embodiment, the data driver may be included in the driving chip IC. Data connection lines electrically connected to the data lines DL may be disposed in the non-display area NDA, and the data connection lines may be electrically connected to the driving chip IC disposed on the rear surface of the base layer BS through the contact structure CS.

The data lines DL may extend along a pixel column. For example, the data lines DL may extend along the second direction DR2 and may be spaced apart from each other along the first direction DR1. Each of the data lines DL may be electrically connected to the pixel circuit of each of the sub-pixels SPX.

The contact structure CS may be disposed in the non-display area NDA. The contact structure CS may include a conductive structure disposed in a hole formed in the base layer BS. Accordingly, the contact structure CS may be a structure for electrically connecting a line disposed on a front surface 100 (refer to FIG. 3) of the base layer BS and a line disposed on a rear surface 200 of the base layer BS. According to an embodiment, the contact structure CS may overlap the driving chip IC in a plan view along the second direction DR2.

A plurality of contact structures CS may be provided. For example, a portion of the contact structures CS may be electrically connected to the scan connection line. Another portion of the contact structures CS may be electrically connected to the data connection line. Accordingly, a data signal output from the driving chip IC may be provided to the sub-pixel SPX via the contact structure CS, the data connection line, and the data line DL. A scan signal output from the driving chip IC may be provided to the sub-pixel SPX via the contact structure CS, the scan connection line, and the scan line SL. However, the disclosure is not limited thereto, and the contact structures CS may electrically connect various types of lines to each other.

According to an embodiment, the contact structures CS may be arranged in a zigzag structure. For example, the contact structures CS may be sequentially arranged in a first row and a second row along a row direction (for example, the first direction DR1), and in an embodiment, at least a portion of the contact structure CS disposed in an n-th column does not overlap the contact structure CS disposed in an (n−1)-th column and an (n+1)-th column along a column direction (for example, the second direction DR2). At least a portion of the contact structure CS disposed in the n-th column may be disposed to be misaligned with the contact structure CS disposed in the (n−1)-th column and the (n+1)-th column along the column direction (for example, the second direction DR2). In this case, the contact structures CS in the non-display area NDA may be more minutely disposed, and electrical signals may be prevented from being crossed.

According to an embodiment, the contact structure CS may have various shapes on a plane. For example, the contact structure CS may have an n-gonal (n is a natural number equal to or greater than 3) shape. However, the disclosure is not limited thereto. For example, the contact structure CS may have a circular shape or an elliptical shape.

The driving chip IC may overlap the display area DA in a plan view. The driving chip IC may be disposed on the rear surface 200 of the base layer BS. The driving chip IC may include the scan driver and the data driver. The driving chip IC may output the data signal to be applied to the data line DL. The driving chip IC may output the scan signal to be applied to the scan line SL.

In an embodiment, the display device DD may further include a printed circuit board. The printed circuit board may also be disposed on the rear surface 200 of the base layer BS and overlap the display area DA in a plan view according to an embodiment. The printed circuit board may be electrically connected to the driving chip IC and the contact structure CS.

FIG. 3 is a schematic cross-sectional view illustrating a display device according to an embodiment. FIG. 3 is a schematic cross-sectional view taken along line A˜A′ of FIG. 2.

Referring to FIG. 3, the display device DD may include a display layer DP and one or more insulating layers disposed on the front surface 100 of the base layer BS. The display device DD may include the driving chip IC and one or more insulating layers disposed on the rear surface 200 of the base layer BS.

According to an embodiment, the display layer DP may be implemented by various types of light sources. For example, the display layer DP may include an inorganic light emitting element (for example, a micro LED or a nano LED) including an inorganic semiconductor or an organic light emitting diode (OLED). However, the disclosure is not particularly limited, and hereinafter, for convenience of description, the disclosure is described based on an embodiment in which the display layer DP includes the OLED.

According to an embodiment, the base layer BS may include layers forming the front surface 100 and layers forming the rear surface 200. After the layers forming the front surface 100 and the layers forming the rear surface 200 are patterned in a same process, each of one surfaces facing each other may be attached by an adhesive layer ADS. According to an embodiment, the adhesive layer ADS may combine a (1-1)-th base layer BS1-1 and a (1-2)-th base layer BS1-2 with each other, and may include various adhesive materials.

The base layer BS may include the first base layer BS1, the barrier layer BAR, and the second base layer BS2 sequentially stacked. The base layer BS may include the first base layer BS1 adjacent to an inside, the second base layer BS2 adjacent to an outside and defining the front surface 100 or the rear surface 200, and the barrier layer BAR disposed between the first base layer BS1 and the second base layer BS2.

One surface of the first base layer BS1 may face the adhesive layer ADS, and another surface of the first base layer BS1 may face the barrier layer BAR. According to an embodiment, the first base layer BS1 may include the (1-1)-th base layer BS1-1 adjacent to the front surface 100 and the (1-2)-th base layer BS1-2 adjacent to the rear surface 200. According to an embodiment, the (1-1)-th base layer BS1-1 and the (1-2)-th base layer BS1-2 may be spaced apart in a thickness direction (for example, a third direction DR3) of the base layer BS.

The second base layer BS2 may be disposed on the barrier layer BAR and may form the front surface 100 or the rear surface 200. According to an embodiment, the second base layer BS2 may include a (2-1)-th base layer BS2-1 adjacent to the front surface 100 and a (2-2)-th base layer BS2-2 adjacent to the rear surface 200. According to an embodiment, the (2-1)-th base layer BS2-1 and the (2-2)-th base layer BS2-2 may be spaced apart in the thickness direction (for example, the third direction DR3) of the base layer BS.

The first base layer BS1 and the second base layer BS2 may include various materials. According to an embodiment, the first base layer BS1 and the second base layer BS2 may include an organic material. For example, the first base layer BS1 and the second base layer BS2 may include a same material and may include polyimide. However, the disclosure is not necessarily limited thereto.

One surface of the barrier layer BAR may contact the first base layer BS1, and another surface of the barrier layer BAR may contact the second base layer BS2. According to an embodiment, the barrier layer BAR may include a first barrier layer BAR1 disposed between the (1-1)-th base layer BS1-1 and the (2-1)-th base layer BS2-1, and a second barrier layer BAR2 disposed between the (1-2)-th base layer BS1-2 and the (2-2)-th base layer BS2-2. According to an embodiment, the first barrier layer BAR1 and the second barrier layer BAR2 may be spaced apart in the thickness direction (for example, the third direction DR3) of the base layer BS.

The barrier layer BAR may include a material different from that of the first base layer BS1 and the second base layer BS2 and may include an inorganic material according to an embodiment. For example, the barrier layer BAR may include one or more of a group of amorphous silicon (a-Si), silicon oxide (SiOx), silicon nitride (SiNx), silicon oxynitride (SiOxNy), aluminum oxide (AlOx), and titanium oxide (TiOx). For example, the barrier layer BAR may have a structure in which a layer including silicon nitride (SiNx) and a layer including silicon oxynitride (SiOxNy) are alternately disposed. Alternatively, the barrier layer BAR may have a structure in which a layer including amorphous silicon (a-Si) and a layer including silicon oxide (SiOx) are alternately disposed. However, the disclosure is not necessarily limited thereto.

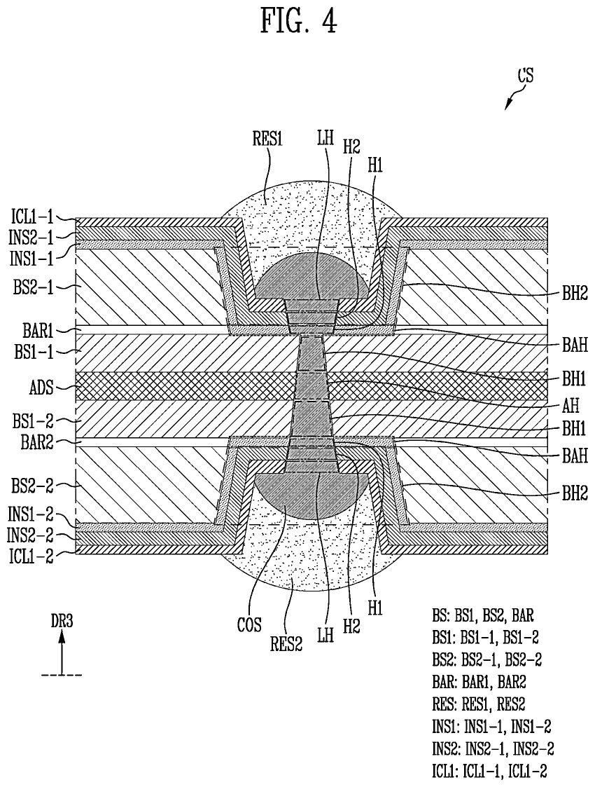

According to an embodiment, the first base layer BS1, the barrier layer BAR, and the second base layer BS2 may form a hole for forming the contact structure CS including a connection portion COS. The hole may be formed by passing through the first base layer BS1, the barrier layer BAR, and the second base layer BS2, and the conductive connection portion COS may be inserted into the hole. This is described further with reference to drawings after FIG. 4.

According to an embodiment, a first insulating layer INS1 and a second insulating layer INS2 may be disposed on the second base layer BS2.

The first insulating layer INS1 may be a buffer layer and may prevent an impurity from being diffused from outside of the display device DD. The first insulating layer INS1 may include a (1-1)-th insulating layer INS1-1 disposed on the front surface 100 and a (1-2)-th insulating layer INS1-2 disposed on the rear surface 200. The (1-1)-th insulating layer INS1-1 and the (1-2)-th insulating layer INS1-2 may be deposited in a same process and include a same material.

The second insulating layer INS2 may be disposed on the first insulating layer INS1. According to an embodiment, a portion of the second insulating layer INS2 may cover an active layer ACT and a gate electrode GE. The second insulating layer INS2 may include a (2-1)-th insulating layer INS2-1 disposed on the front surface 100 and a (2-2)-th insulating layer INS2-2 disposed on the rear surface 200. The (2-1)-th insulating layer INS2-1 and the (2-2)-th insulating layer INS2-2 may be deposited in a same process and include a same material.

According to an embodiment, each of the first insulating layer INS1 and the second insulating layer INS2 may independently include an inorganic material, and the inorganic material may include, for example, one or more of silicon oxide (SiOx), silicon nitride (SiNx), silicon oxynitride (SiOxNy), aluminum oxide (AlOx), and titanium oxide (TiOx).

According to an embodiment, the display device DD may include the active layer ACT, a gate insulating layer G1, the gate electrode GE, a first transistor electrode TE1, a second transistor electrode TE2, a first conductive layer ICL1, a first interlayer insulating layer ILD1, a bridge pattern layer BRP, and a second interlayer insulating layer ILD2.

The active layer ACT may be disposed on the (1-1)-th insulating layer INS1-1 and covered by the (2-1)-th insulating layer INS2-1 in a plan view. According to an embodiment, the active layer ACT may include one or more of a group of polysilicon, low temperature polycrystalline silicon (LTPS), amorphous silicon, and an oxide semiconductor. The active layer ACT may include a first contact area contacting the first transistor electrode TE1 and a second contact area contacting the second transistor electrode TE2. The first contact area and the second contact area may be a semiconductor pattern in which an impurity is doped. An area between the first contact area and the second contact area may be a channel area. The channel area may be an intrinsic semiconductor pattern which is not doped with an impurity.

The gate insulating layer G1 may be disposed between the gate electrode GE and the active layer ACT. The gate insulating layer G1 may include one or more of the inorganic materials described above with reference to the first and second insulating layers INS1 and INS2.

The gate electrode GE may be disposed on the gate insulating layer G1 and may be disposed on the channel area of the active layer ACT with the gate insulating layer G1 interposed therebetween. The gate electrode GE may include a conductive material.

The first transistor electrode TE1 and the second transistor electrode TE2 may be disposed on the first insulating layer INS1. The first transistor electrode TE1 may electrically contact the first contact area of the active layer ACT by passing through the first insulating layer INS1, and the second transistor electrode TE2 may electrically contact the second contact area of the active layer ACT by passing through the first insulating layer INS1. For example, the first transistor electrode TE1 may be a drain electrode and the second transistor electrode TE2 may be a source electrode, but the disclosure is not limited thereto. According to an embodiment, the first transistor electrode TE1 may be electrically connected to a first electrode ELT1 through one contact portion.

The first conductive layer ICL1 may include a (1-1)-th conductive layer ICL1-1 disposed on the (2-1)-th insulating layer INS2-1 and a (1-2)-th conductive layer ICL1-2 disposed on the (2-2)-th insulating layer INS2-2. The first conductive layer ICL1 may be patterned in a same process and may include a same material as the first and second transistor electrodes TE1 and TE2. The first conductive layer ICL1 may be a source/drain electrode layer.

The first conductive layer ICL1 may be electrically connected to one or more lines included in the display layer DP (for example, the pixel circuit or lines electrically connected to the pixel circuit). The first conductive layer ICL1 may be electrically connected to the connection portion COS. For example, the (1-1)-th conductive layer ICL1-1 may be electrically connected to a portion of the connection portion COS adjacent to the front surface 100, and the (1-2)-th conductive layer ICL1-2 may be electrically connected to another portion of the connection part COS adjacent to the rear surface 200.

According to an embodiment, the first conductive layer ICL1 does not contact the first base layer BS1 when a process of forming the connection portion COS is performed. Referring to a comparative example, when the conductive material is disposed on the first base layer BS1 including the organic material, a risk that a conductive material is diffused into the first base layer BS1 may occur. However, according to an embodiment, when a laser process for forming a hole in the base layer BS is performed, the first conductive layer ICL1 is not directly adjacent to the first base layer BS1, and the above-mentioned risk may be reduced.

The first interlayer insulating layer ILD1 may include a (1-1)-th interlayer insulating layer ILD1-1 disposed on the front surface 100 and a (1-2)-th interlayer insulating layer ILD1-2 disposed on the rear surface 200. The (1-1)-th interlayer insulating layer ILD1-1 and the (1-2)-th interlayer insulating layer ILD1-2 may be deposited in a same process and include a same material. The first interlayer insulating layer ILD1 may include an organic material. However, the disclosure is not limited thereto.

According to an embodiment, the (1-1)-th interlayer insulating layer ILD1-1 may be disposed on the (1-1)-th conductive layer ICL1-1, and the (1-2)-th interlayer insulating layer ILD1-2 may be disposed on the (1-2)-th conductive layer ICL1-2.

The bridge pattern layer BRP may be disposed on the (1-1)-th interlayer insulating layer ILD1-1 to be electrically connected to the first transistor electrode TE1, and may be electrically connected to the first electrode ELT1.

The second interlayer insulating layer ILD2 may include a (2-1)-th interlayer insulating layer ILD2-1 disposed on the front surface 100 and a (2-2)-th interlayer insulating layer ILD2-2 disposed on the rear surface 200. The (2-1)-th interlayer insulating layer ILD2-1 and the (2-2)-th interlayer insulating layer ILD2-2 may be deposited in a same process and include a same material. The second interlayer insulating layer ILD2 may include an organic material. However, the disclosure is not limited thereto.

According to an embodiment, the (2-1)-th interlayer insulating layer ILD2-1 may be disposed on the (1-1)-th interlayer insulating layer ILD1-1, and the (2-2)-th interlayer insulating layer ILD2-2 may be disposed on the (1-2)-th interlayer insulating layer ILD1-2. According to an embodiment, the (2-1)-th interlayer insulating layer ILD2-1 may be a via layer and may be a planarization layer.

According to an embodiment, the driving chip IC may be disposed on the (2-2)-th insulating layer INS2-2. The driving chip IC may be electrically connected to the (1-2)-th conductive layer ICL1-2 electrically connected to the connection portion COS. Accordingly, the driving chip IC may be electrically connected to a line on the front surface 100.

According to an embodiment, the display device DD may include a light emitting element LD, a pixel defining layer PDL, and an encapsulation layer TFE disposed on the (2-1)-th interlayer insulating layer ILD2-1 as a configuration for forming the display layer DP.

The light emitting element LD may be disposed on the (2-1)-th interlayer insulating layer ILD2-1 (for example, the via layer). The light emitting element LD may include the first electrode ELT1, a light emitting layer EL, and a second electrode ELT2. According to an embodiment, the light emitting layer EL may be disposed in an area defined by the pixel defining layer PDL. The pixel defining layer PDL may be adjacent to a periphery of the light emitting layer EL. One surface of the light emitting layer EL may be electrically connected to the first electrode ELT1, and another surface of the light emitting layer EL may be electrically connected to the second electrode ELT2.

The first electrode ELT1 may be an anode electrode for the light emitting layer EL, and the second electrode ELT2 may be a common electrode (or a cathode electrode) for the light emitting layer EL. According to an embodiment, the first electrode ELT1 and the second electrode ELT2 may include a conductive material. For example, the first electrode ELT1 may include a conductive material having a reflective property, and the second electrode ELT2 may include a transparent conductive material. However, the disclosure is not limited thereto.

The light emitting layer EL may have a multilayer thin film structure including a light generation layer. The light emitting layer EL may include a hole injection layer for injecting a hole, a hole transport layer having excellent hole transportability and suppressing a movement of an electron which is not combined in the light generation layer to increase a chance of recombination of the hole and the electron, the light generation layer that emits light by the recombination of the injected electron and hole, a hole blocking layer for suppressing a movement of a hole which is not combined in the light generation layer, an electron transport layer for smoothly transporting the electron to the light generation layer, and an electron injection layer for injecting the electron. The light emitting layer EL may emit light based on an electrical signal provided from the first electrode ELT1 and the second electrode ELT2.

The pixel defining layer PDL may be disposed on the (2-1)-th interlayer insulating layer ILD2-1 (for example, the via layer) to define a position where the light emitting layer EL is disposed. According to an embodiment, a portion of the pixel defining layer PDL may be disposed at an edge of the display area DA adjacent to the non-display area NDA.

According to an embodiment, the pixel defining layer PDL may include an organic material. According to an embodiment, the pixel defining layer PDL may include one or more of a group of acrylic resin, epoxy resin, phenol resin, polyamide resin, and polyimide resin. However, the disclosure is not limited thereto. The pixel defining layer PDL may include an inorganic material.

The encapsulation layer TFE may be disposed on the light emitting element LD (or the second electrode ELT2). The encapsulation layer TFE may offset a step difference generated by the light emitting element LD and the pixel defining layer PDL. The encapsulation layer TFE may include a plurality of insulating layers covering the light emitting element LD. According to an embodiment, the encapsulation layer TFE may have a structure in which an inorganic layer and an organic layer are alternately stacked. According to an embodiment, the encapsulation layer TFE may have a structure in which a first inorganic layer TFE1, an organic layer TFE2, and a second inorganic layer TFE3 are sequentially stacked. According to an embodiment, the encapsulation layer TFE may be a thin film encapsulation layer.

Hereinafter, a contact structure CS according to an embodiment is described with reference to FIGS. 4 to 10. For convenience of explanation, a further description of components and technical aspects previously describe may be omitted.

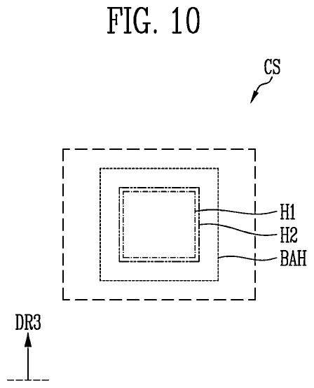

FIGS. 4 to 9 are schematic cross-sectional views illustrating a display device including a contact structure according to an embodiment. FIG. 10 is a schematic plan view illustrating a first hole, a second hole, and a third hole according to an embodiment.

Referring to FIG. 4, a display device DD including a contact structure CS according to an embodiment is described. FIG. 4 is a schematic cross-sectional view illustrating the display device DD including the contact structure CS according to an embodiment.

According to an embodiment, the contact structure CS may be formed in the non-display area NDA and may electrically connect the line on the front surface 100 and the line on the rear surface 200. For example, the contact structure CS may include the connection portion COS electrically connecting the line on the front surface 100 and the line on the rear surface 200, and may include holes for forming the connection portion COS.

According to an embodiment, the contact structure CS may include a hole in which the connection portion COS may be disposed. For example, the contact structure CS may include a first base hole BH1, an adhesion hole AH, a barrier hole BAH, a second base hole BH2, a first hole H1, a second hole H2, and a line hole LH. The first base hole BH1, the adhesion hole AH, the barrier hole BAH, the second base hole BH2, the first hole H1, the second hole H2, and the line hole LH may be fluidly (fluidically) connected (or coupled) each other.

The first base hole BH1 may be included in the first base layer BS1. The first base hole BH1 may be formed by the first base layer BS1. For example, the first base hole BH1 may include a hole formed by the (1-1)-th base layer BS1-1 and a hole formed by the (1-2)-th base layer BS1-2.

The barrier hole BAH may be included in the barrier layer BAR. The barrier hole BAH may be formed by the barrier layer BAR. For example, the barrier hole BAH may include a hole formed by the first barrier layer BAR1 and a hole formed by the second barrier layer BAR2.

The second base hole BH2 may be included in the second base layer BS2. The second base hole BH2 may be formed by the second base layer BS2. For example, the second base hole BH2 may include a hole formed by the (2-1)-th base layer BS2-1 and a hole formed by the (2-2)-th base layer BS2-2.

The first hole H1 may be included in the first insulating layer INS1. The first hole H1 may be formed by the first insulating layer INS1. For example, the first hole H1 may include a hole formed by the (1-1)-th insulating layer INS1-1 and a hole formed by the (1-2)-th insulating layer INS1-2.

The second hole H2 may be included in the second insulating layer INS2. The second hole H2 may be formed by the second insulating layer INS2. For example, the second hole H2 may include a hole formed by the (2-1)-th insulating layer INS2-1 and a hole formed by the (2-2)-th insulating layer INS2-2.

The line hole LH may be included in the first conductive layer ICL1. The line hole LH may be formed by the first conductive layer ICL1. For example, the line hole LH may include a hole formed by the (1-1)-th conductive layer ICL1-1 and a hole formed by the (1-2)-th conductive layer ICL1-2.

According to an embodiment, a process for forming the first base hole BH1 formed in the (1-1)-th base layer BS1-1 and a process for forming the first base hole BH1 formed in the (1-2)-th base layer BS1-2 may be performed in a single process. For example, in order to form the first base hole BH1, a laser process may be performed, and a laser may be applied in a direction from an area adjacent to the rear surface 200 to an area adjacent to the front surface 100. According to an embodiment, the first base hole BH1 and the adhesion hole AH may have a trapezoidal shape in a cross-section of the contact structure CS. In this case, a technical effect that a process step for forming the first base hole BH1 for the first base layer BS1 is simplified may be provided.

According to an embodiment, a planar size of the barrier hole BAH and a planar size of the second base hole BH2 may correspond to each other. For example, the barrier hole BAH and the second base hole BH2 may be formed in a same process. For example, etching masks used to form the barrier hole BAH and the second base hole BH2 may be equal to each other. The second base layer BS2 and the barrier layer BAR may be etched in a same process.

In the present specification, when different holes have sizes corresponding to each other, the different holes may be manufactured in a same etching process.

According to an embodiment, an upper surface of the barrier layer BAR may entirely contact the second base layer BS2. Accordingly, in an embodiment, the barrier layer BAR does not generally protrude from a lower surface of the second base layer BS2. According to an embodiment, in an area adjacent to the barrier hole BAH and the second base hole BH2, the barrier layer BAR and the second base layer BS2 may form a continuous side surface.

According to an embodiment, the size of the barrier hole BAH may be greater than the size of the first base hole BH1. For example, the size of the barrier hole BAH may be greater than the size of the first hole H1, the size of the second hole H2, and size of the line hole LH. According to an embodiment, the first hole H1, the second hole H2, and the line hole LH may have sizes corresponding to each other. For example, in an area adjacent to the first hole H1 and the second hole H2, the first insulating layer INS1 and the second insulating layer INS2 may form a continuous side surface.

According to an embodiment, the second base layer BS2 may form an angle with a base surface in an area adjacent to an area where holes are formed. For example, a side surface of the second base layer BS2 may form an angle other than an obtuse angle with a plane on which the first base layer BS1 is disposed.

According to an embodiment, the first base layer BS1 does not include an under-cut structure at a position adjacent to an area where the first base hole BH1 is formed. For example, the first base hole BH1 may include a side surface directly adjacent to an area where the connection portion COS is disposed, and the directly adjacent side surface may include a tapered surface.

Referring to a comparative example, when the first base layer BS1 includes an under-cut structure in the area where the connection portion COS is provided, a risk that at least a portion of layers including an inorganic material penetrate an under-cut area may occur.

However, according to an embodiment, the first base layer BS1 may include a tapered surface that does not include an under-cut structure, and thus, the above-described risk may be prevented and structural stability may be improved. Such a technical effect may be generated since a layer including an inorganic material is not disposed on the first base layer BS1 when a laser process for forming the holes BH1 and AH passing through the first base layer BS1 and the adhesive layer ADS is performed. This is described in further detail below.

According to an embodiment, the connection portion COS may be disposed in the first base hole BH1, the adhesion hole AH, the barrier hole BAH, the second base hole BH2, the first hole H1, the second hole H2, and the line hole LH.

At least a portion of the connection portion COS may be electrically connected to the (1-1)-th conductive layer ICL1-1 disposed on the front surface 100, and another portion of the connection portion COS may be electrically connected to the (1-2)-th conductive layers ICL1-2 disposed on the rear surface 200. A portion of the connection portion COS adjacent to the front surface 100 may include a curved surface. A portion of the connection portion COS adjacent to the rear surface 200 may include a curved surface. The connection portion COS may be covered by a resin portion RES.

The connection portion COS may include metal. For example, the connection portion COS may include silver (Ag) as a conductive material. The connection portion COS may include a structure in which an ink including a metal material is cured. For example, the connection portion COS may have a state in which an ink including silver is cured (for example, light-cured). However, the disclosure is not limited thereto. For example, the connection portion COS may be formed through a sputtering process or may be provided by applying a conductive paste.

The resin portion RES may be disposed on the connection portion COS to cover an upper surface of the connection portion COS. The resin portion RES may entirely cover the upper surfaces of the exposed connection portion COS. The resin portion RES may include a first resin portion RES1 disposed adjacent to the front surface 100 in the second base hole BH2 and a second resin portion RES2 disposed adjacent to the rear surface 200 in the second base hole BH2. The resin portion RES may protect the connection portion COS from a foreign substance such as moisture. The resin portion RES may include various polymer resins, and an example thereof is not particularly limited.

According to an embodiment, the first hole, the second hole H2, and the third hole H3 may have various shapes in a plan view. For example, referring to FIG. 10, the first hole, the second hole H2, and the third hole H3 may have a quadrangular shape. However, the disclosure is not necessarily limited thereto.

In addition, in a plan view, a size relationship of the first hole, the second hole H2, and the third hole H3 may be variously changed. For example, as shown in FIG. 10, the barrier hole BAH may have a size greater than that of the first hole H1 and the second hole H2. However, the disclosure is not necessarily limited thereto, and a size relationship may be properly changed according to a time point of a process of etching the barrier layer BAR, the first insulating layer INS1, and the second insulating layer INS2 to form the respective barrier hole BAH, first hole H1, and second hole H2.

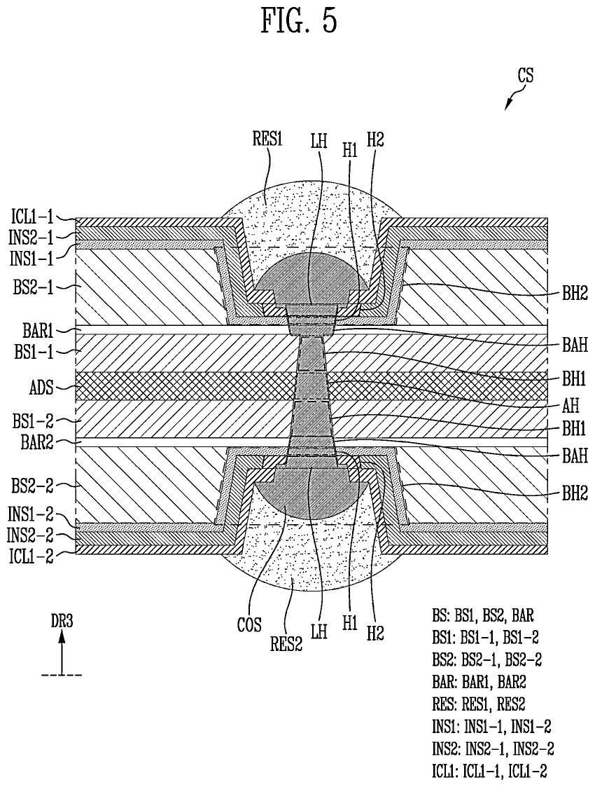

Next, with reference to FIG. 5, a display device DD including a contact structure CS according to an embodiment is described. FIG. 5 is a schematic cross-sectional view illustrating the display device DD including the contact structure CS according to an embodiment.

The contact structure CS according to an embodiment shown in FIG. 5 is different from the contact structure CS according an embodiment shown in FIG. 4, in that the barrier hole BAH is formed in a process different from a process for patterning the second base layer BS2.

According to an embodiment, after an etching process for forming the second base hole BH2 is performed, an etching process for forming the barrier hole BAH may be performed. According to an embodiment, a size of the barrier hole BAH may be less than that of the second base hole BH2. According to an embodiment, at least a portion of the barrier layer BAR does not overlap the second base layer BS2 in a plan view. At least a portion of the barrier layer BAR may protrude from a lower surface of the second base layer BS2 toward the connection portion COS.

According to an embodiment, etching masks used to form the barrier hole BAH and the first hole H1 may be equal to each other. The barrier layer BAR and the first insulating layer INS1 may be etched in a same process. According to an embodiment, after an etching process for the first insulating layer INS1 is performed, an etching process for the second insulating layer INS2 may be performed.

According to an embodiment, the barrier hole BAH and the first hole H1 may have corresponding sizes. The second hole H2 may have a size greater than that of the barrier hole BAH and the first hole H1.

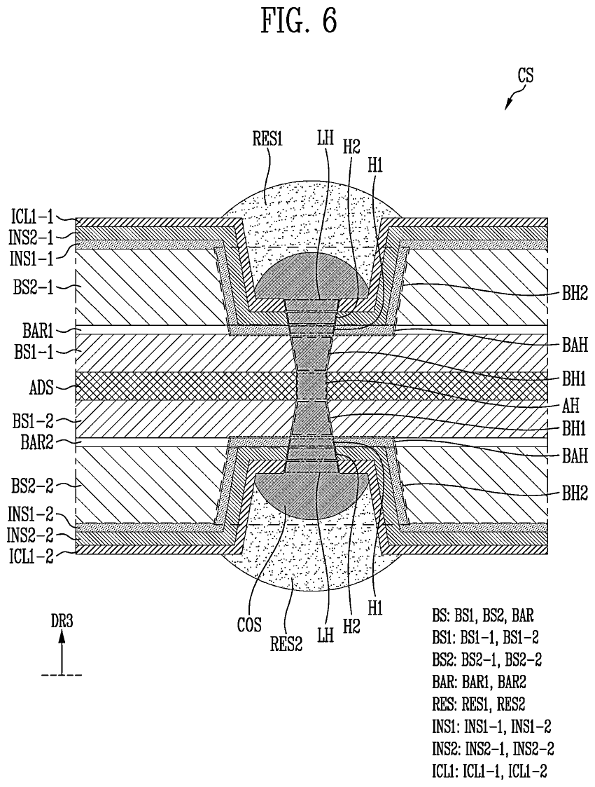

Next, with reference to FIG. 6, a display device DD including a contact structure CS according to an embodiment is described. FIG. 6 is a schematic cross-sectional view illustrating the display device DD including the contact structure CS according to an embodiment.

The contact structure CS according to an embodiment is different from the contact structure CS according to an embodiment described above, in that, a shape of the connection portion COS has a wider cross-section toward the front surface 100 or the rear surface 200 in an area passing through the first base layer BS1 and the adhesive layer ADS.

According to an embodiment, forming the first base hole BH1 formed in the (1-1)-th base layer BS1-1 and the first base hole BH1 formed in the (1-2)-th base layer BS1-2 may be performed in different processes. For example, in order to form the first base hole BH1 formed in the (1-1)-th base layer BS1-1, a first laser process may be performed, and in the first laser process, a laser may be applied in a direction from an area adjacent to the front surface 100 to an area adjacent to the rear surface 200. In order to form the first base hole BH1 formed in the (1-2)-th base layer BS1-2, a second laser process different from the first laser process may be performed, and in the second laser process, a laser may be applied in a direction from the area adjacent to the rear surface 200 to the area adjacent to the front surface 100. According to an embodiment, the first base hole BH1 and the adhesion hole AH may have an hourglass shape in a cross-section of the contact structure CS. In this case, since the laser for forming the first base hole BH1 may be applied only to an area of a relatively thin thickness, necessity for applying a laser having an excessively strong intensity may be reduced, and thus, a risk that the base layer BS or the like is damaged by a laser may be reduced.

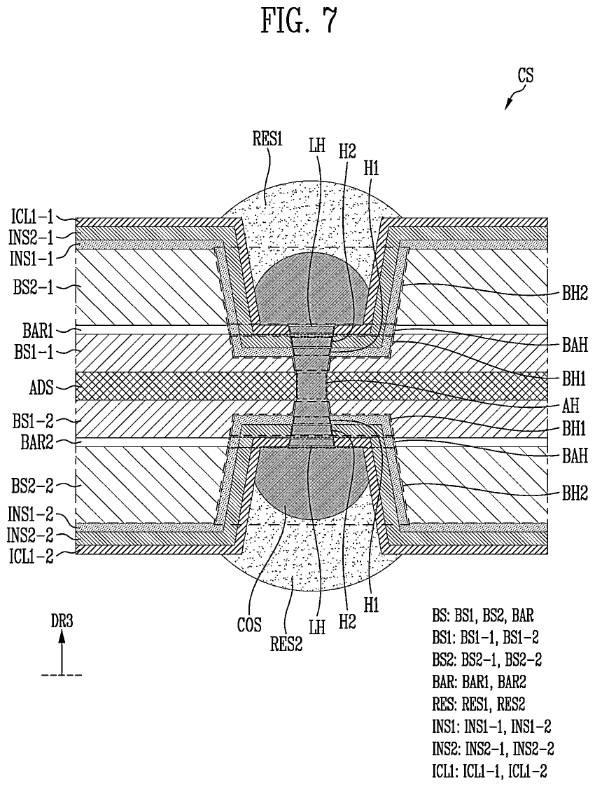

Next, with reference to FIG. 7, a display device DD including a contact structure CS according to an embodiment is described. FIG. 7 is a schematic cross-sectional view illustrating the display device DD including the contact structure CS according to an embodiment.

The contact structure CS according to an embodiment of FIG. 7 is different from the contact structure CS according to an embodiment described above, in that a portion of the first base layer BS1 is removed and thus, at least a portion of each of the barrier layer BAR, the first insulating layer INS1, and the second insulating layer INS2 is formed in a cavity formed in the first base layer BS1.

According to an embodiment, the first base hole BH1 having a size greater than that of an area where the connecting portion COS is to be disposed may be formed. For example, a portion of the first base hole BH1 defined outside of an area where the connection portion COS is directly disposed may be formed by an etching process, and then a laser process may be performed to provide another portion of the first base hole BH1. According to an embodiment, the first base hole BH1 may be manufactured by performing an etching process for a wider area and a deeper area. In this case, a laser process for the first base layer BS1 and the adhesive layer ADS may be applied from a relatively deeper position, and a risk that the base layer BS is damaged by a laser may be reduced.

According to an embodiment, the barrier hole BAH and the second base hole BH2 may be formed in a same etching process. Accordingly, an upper surface of the barrier layer BAR may entirely contact a lower surface of the second base layer BS2.

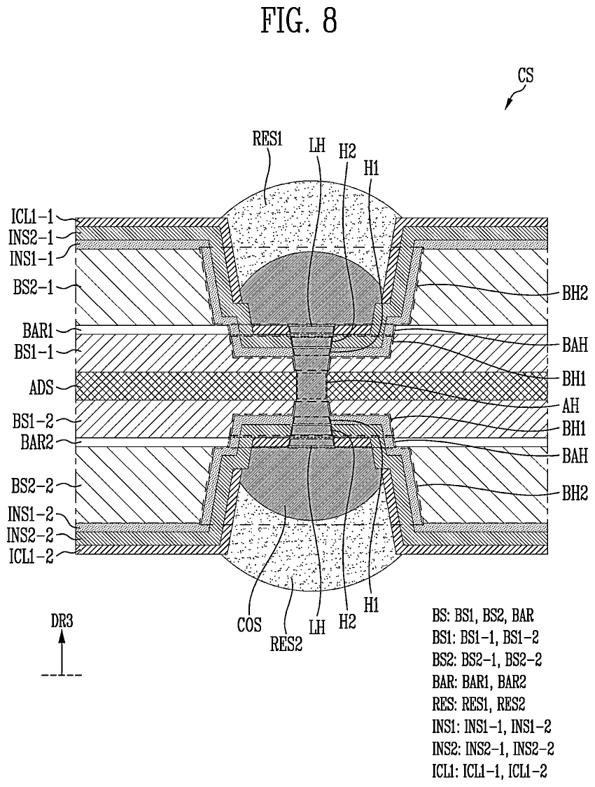

Next, with reference to FIG. 8, a display device DD including a contact structure CS according to an embodiment is described. FIG. 8 is a schematic cross-sectional view illustrating the display device DD including the contact structure CS according to an embodiment.

The contact structure CS according to an embodiment of FIG. 8 is different from the contact structure CS according to an embodiment described above, in that a portion of the first base layer BS1 is removed, and at least a portion of each of the barrier layer BAR, the first insulating layer INS1, and the second insulating layer INS2 is disposed in a cavity formed in the first base layer BS1. Forming the first base hole BH1 and the barrier hole BAH and forming the second base hole BH2 are formed in different processes.

According to an embodiment, after the second base layer BS2 is etched to form the second base hole BH2, the first base hole BH1 and the barrier hole BAH may be formed in an area relatively narrower than that of the second base hole BH2.

According to an embodiment, similar to the example described above, a risk that the base layer BS is damaged by a laser process may be prevented, and the connection portion COS may be suitably formed in a relatively wide area.

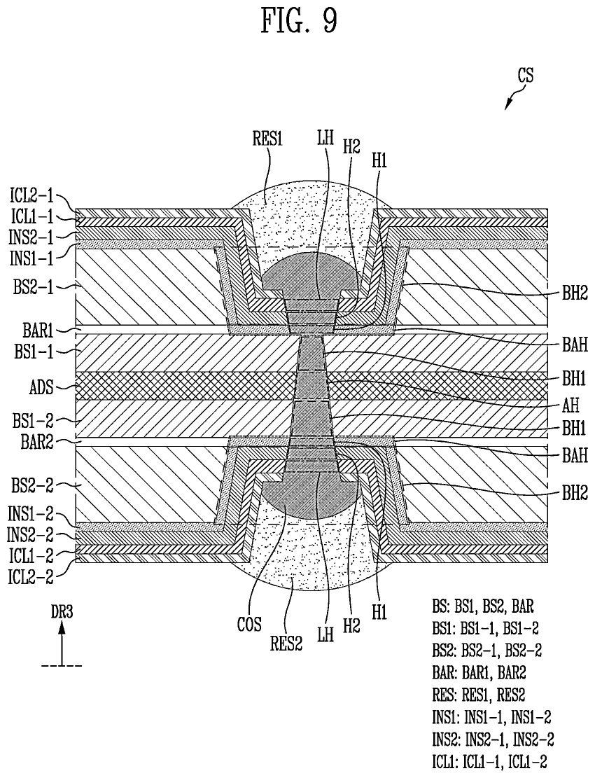

Next, with reference to FIG. 9, a display device DD including a contact structure CS according to an embodiment is described. FIG. 9 is a schematic cross-sectional view illustrating the display device DD including the contact structure CS according to an embodiment.

The contact structure CS according to an embodiment shown in FIG. 9 is different from the contact structure CS according to an embodiment described above, in that a second conductive layer ICL2 is further disposed on the first conductive layer ICL1.

According to an embodiment, the connection portion COS may be electrically connected to the first conductive layer ICL1 and the second conductive layer ICL2 simultaneously. The second conductive layer ICL2 may be disposed on one surface of the first conductive layer ICL1. For example, the second conductive layer ICL2 may include a (2-1)-th conductive layer ICL2-1 on the front surface 100 and a (2-2)-th conductive layer ICL2-2 on the rear surface 200. The (2-1)-th conductive layer ICL2-1 may be disposed on the (1-1)-th conductive layer ICL1-1. The (2-2)-th conductive layer ICL2-2 may be disposed on the (1-2)-th conductive layer ICL1-2. According to an embodiment, the second conductive layer ICL2 may be formed in a same process and may include a same material as the bridge pattern layer BRP described above. However, the disclosure is not limited thereto.

A portion of the connection portion COS may be a line on the front surface 100 and may be electrically connected to the (1-1)-th conductive layer ICL1-1 and the (2-1)-th conductive layer ICL2-1. Another portion of the connection portion COS may be a line on the rear surface 200 and may be electrically connected to the (1-2)-th conductive layer ICL1-2 and the (2-2)-th conductive layer ICL2-2.

According to an embodiment shown in FIG. 9, a resistance of lines connected to the connection portion COS may be relatively reduced, and thus, reliability of an electrical signal supplied through the connection portion COS may be improved.

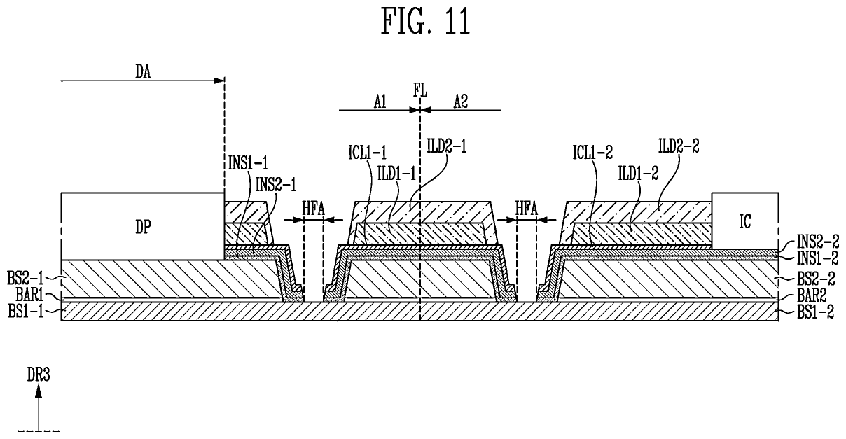

Hereinafter, with reference to FIGS. 11 to 17, a method of manufacturing a display device DD according to an embodiment is described. For convenience of explanation, a further description of components and technical aspects previously described may be omitted.

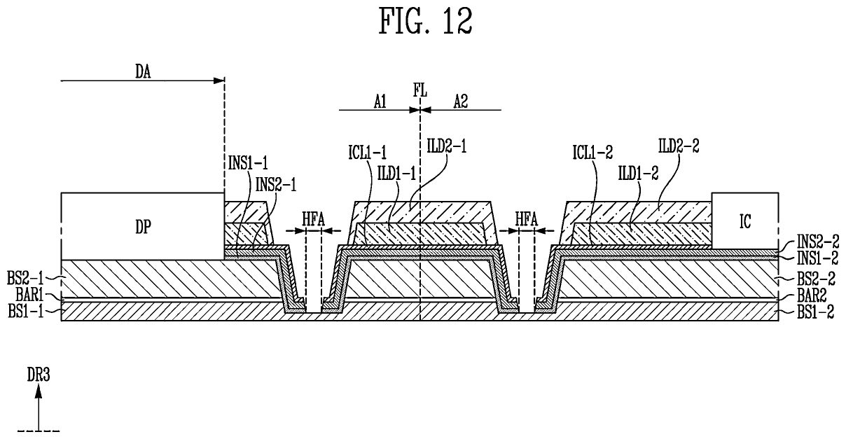

FIGS. 11 to 17 are schematic cross-sectional views illustrating a method of manufacturing a display device according to an embodiment. FIGS. 11 and 12 are cross-sectional views illustrating a process step before a first area A1 and a second area A2 overlap on a plane. FIGS. 11 and 12 are cross-sectional views illustrating a processing step after the first area A1 and the second area A2 overlap on a plane.

Referring to FIGS. 11 and 12, a base layer BS including the first area A1 and the second area A2 may be manufactured. For example, the display layer DP may be disposed in the first area A1 on the base layer BS, and the driving chip IC may be disposed in the second area A2 on the base layer BS. In an embodiment, the printed circuit board may be disposed in the second area A2 on the base layer BS.

According to an embodiment, the first area A1 and the second area A2 may be divided by a division line FL that is folded or cut in a later process.

In the following drawing, for convenience of description, the display layer DP is schematically shown.

The base layer BS may be provided. For example, the first base layer BS1, the barrier layer BAR, and the second base layer BS2 may be sequentially stacked.

The first insulating layer INS1, the second insulating layer INS2, the first conductive layer ICL1, the first interlayer insulating layer ILD1, and the second interlayer insulating layer ILD1 may be disposed on the second base layer BS2.

According to an embodiment, the first barrier layer BAR1, the (2-1)-th base layer BS2-1, the (1-1)-th insulating layer INS1-1, the (2-1)-th insulating layer INS2-1, and the (1-1)-th conductive layer ICL1-1 may form a hole structure in the first area A1. The hole structure formed in the first area A1 may be a hole structure for providing at least a portion of the connection portion COS to the front surface 100. The second barrier layer BAR2, the (2-2)-th base layer BS2-2, the (1-2)-th insulating layer INS1-2, the (2-2)-th insulating layer INS2-2, and the (1-2)-th conductive layer ICL1-2 may form a hole structure in the second area A2. The hole structure formed in the second area A2 may be a hole structure for providing at least a portion of the connection portion COS to the rear surface 200. The hole structures formed in the respective areas A1 and A2 may refer to the holes described with reference to FIGS. 4 to 9.

According to an embodiment, when forming the hole structures, at least a portion of the first base layer BS1 is not etched (FIG. 11). However, the disclosure is not limited thereto. For example, in an embodiment, when forming the hole structures, at least a portion of the first base layer BS1 may be etched (FIG. 12). In this case, as described with reference to FIGS. 7 and 8, a risk that configurations are damaged by a later laser process may be reduced.

According to an embodiment, a process for patterning the base layer BS and conductive layers and insulating layers on the base layer BS may be performed based on a typical photolithography process, and an etching method, a deposition method, and the like are not limited to a special example.

According to an embodiment, in order to form the display layer DP, the light emitting element LD may be formed by various methods. For example, when the light emitting element LD includes the OLED, the light emitting layer EL of the light emitting element LD may be manufactured by sequentially depositing organic materials. The display layer DP may be disposed on at least a partial area, and thus, the display area DA may be defined. In addition, when forming the display layer DP, an organic layer formed on the base layer BS may be formed. At this time, as a structure formed in a same process as a portion of the organic layer (for example, the encapsulation film TFE) of the display layer DP, the organic layer formed in a hole formation area HFA may be removed.

According to an embodiment, after the first conductive layer ICL1 is patterned, the first conductive layer ICL1 may be quickly removed in the hole formation area HFA. When the first conductive layer ICL1 and the first base layer BS1 contact each other, a conductive material of the first conductive layer ICL1 may be diffused in the first base layer BS1. However, according to an embodiment, the first conductive layer ICL1 does not substantially contact the first base layer BS1, and a risk that the first base layer BS1 is contaminated by the conductive material may be prevented.

According to an embodiment, the (1-1)-th conductive layer ICL1-1 may be electrically connected to at least partial line of the display layer DP, and the (1-2)-th conductive layer ICL1-2 may be electrically connected to the driving chip IC.

According to an embodiment, at least a portion of the first base layer BS1 may be exposed. Before a subsequent process is performed, at least a portion of the first base layer BS1 may be exposed in the hole formation area HFA, which is a position corresponding to the formed hole structure. For example, in an embodiment, the barrier layer BAR, the first insulating layer INS1, and the second insulating layer INS2 do not cover at least a portion of the hole formation area HFA of the first base layer BS1. The hole formation area HFA may be an area to which a laser of a subsequent laser process is applied, and the laser process may be performed, and thus, at least a portion of the first base layer BS1 in an area overlapping the hole formation area HFA in a plan view may be removed.

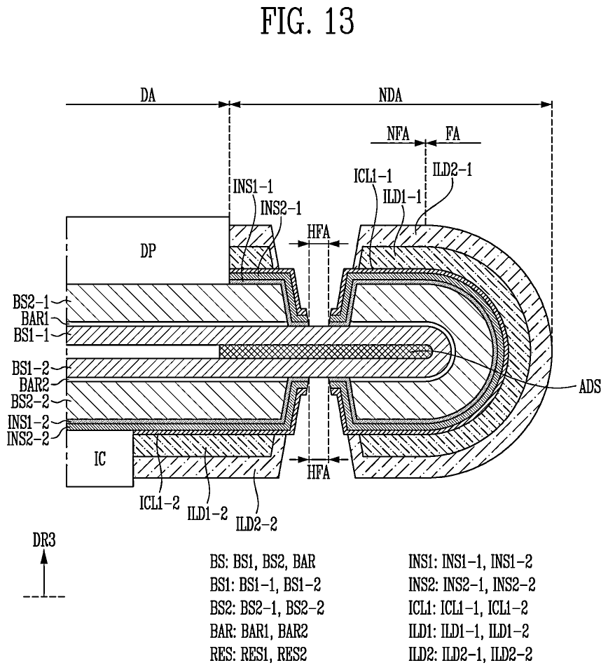

Referring to FIG. 13, a portion of the base layer BS in the first area A1 and a portion of the base layer BS in the second area A2 may be manufactured to overlap on a plane.

For example, based on the division line FL, the previously prepared base layer BS and structures on the base layer BS may be folded. Accordingly, at least a portion of the first area A1 and the second area A2 may be provided as a non-folding area NFA, and at least another portion of the first area A1 and the second area A2 may be provided as a folding area FA. In addition, the adhesive layer ADS may be interposed between the (1-1)-th base layer BS1-1 and the (1-2)-th base layer BS1-2, and thus, the (1-1)-th base layer BS1-1 and the (1-2)-th base layer BS1-2 may be combined with each other.

However, the disclosure is not necessarily limited thereto. For example, according to an embodiment, based on the division line FL, the previously prepared base layer BS and the structures on the base layer BS may be cut and combined (for example, laminated) with each other. In this case, the dead space of the display device DD may be further reduced.

The front surface 100 and the rear surface 200 may be defined. For example, an area where the display layer DP is disposed may be defined as an area corresponding to the front surface 100, and an area where the driving chip IC is disposed may be defined as an area corresponding to the rear surface 200.

Holes defined on the front surface 100 and the holes defined on the rear surface 200 may overlap each other in a plan view. For example, a hole defined by the first barrier layer BAR1, the (2-1)-th base layer BS2-1, the (1-1)-th insulating layer INS1-1, the (2-1)-th insulating layer INS2-1, and the (1-1)-th conductive layer ICL1-1, and a hole defined by the second barrier layer BAR2, the (2-2)-th base layer BS2-2, the (1-2)-th insulating layer INS1- 2, the (2-2)-th insulating layer INS2-2, and the (1-2)-th conductive layer ICL1-2 may overlap each other in a plan view.

At least a portion of the first base layer BS1 may maintain an exposed state. For example, at least a portion of the (1-1)-th base layer BS1-1 may be exposed, and at least a portion of the (1-2)-th base layer BS1-2 may be exposed.

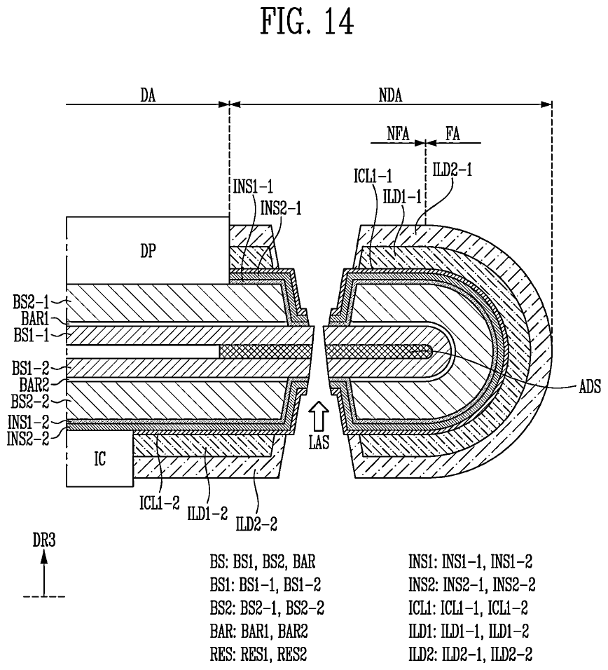

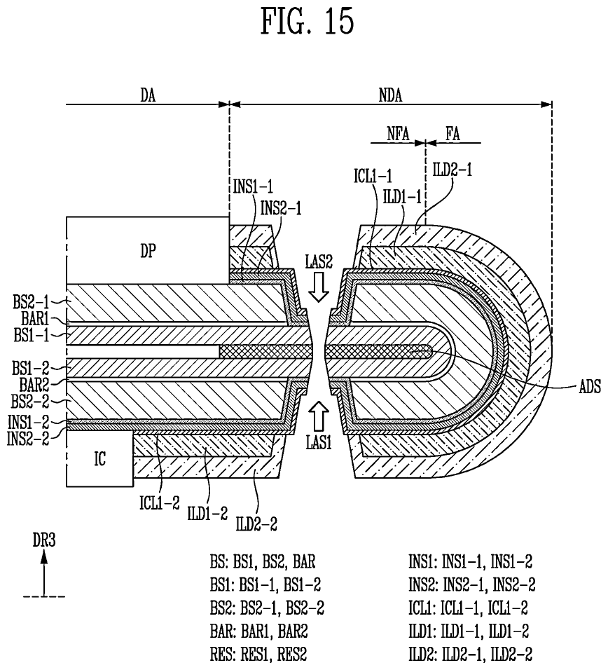

Referring to FIGS. 14 and 15, a laser process may be performed, and thus, a space for disposing (or providing) the connection portion COS may be provided.

The laser process may be performed on the hole formation area HFA. For example, a laser LAS may be applied to the hole formation area HFA, and a portion of the first base layer BS1 and a portion of the adhesive layer ADS overlapping the hole formation area HFA on a plane may be removed.

According to an embodiment (refer to FIG. 14), the laser LAS may be applied within a single process in one direction. In this case, a hole for the (1-1)-th base layer BS1-1, the (1-2)-th base layer BS1-2, and the adhesive layer ADS may be formed within a single process.

Alternatively, according to an embodiment (refer to FIG. 15), in the hole formation area HFA, each of a first laser LAS1 applied in one direction and a second laser LAS2 applied in another direction may be applied into the hole formation area HFA. Accordingly, similarly, a portion of the first base layer BS1 and a portion of the adhesive layer ADS overlapping the hole formation area HFA on a plane may be removed, and a hole structure having an hourglass shape in a cross-section may be provided.

Referring to a comparative example, when a laser process is performed, a layer including an inorganic material may have laser transmittance higher than that of a layer including an organic material. For example, the layer including the inorganic material (for example, the barrier layer BAR) may substantially transmit a laser. In this case, laser energy is applied to an adjacent area other than the hole formation area HFA, and thus, a concern that a portion of the first base layer BS1 may be removed exists. In this case, an under-cut structure may occur, and thus the first base layer BS1 may be damaged.

However, according to an embodiment, the laser process may be performed in a state in which the layer including the inorganic material is not disposed in the hole formation area HFA, and as a result, the above-described under-cut structure does not occur.

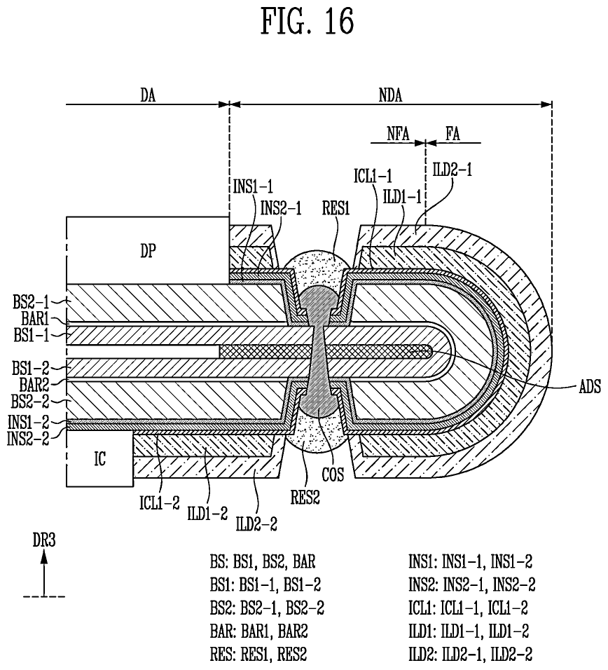

Referring to FIG. 16, the connection portion COS may be supplied (or disposed) to the hole structure formed in the hole formation area HFA, and the resin portion RES may be applied on the connection portion COS. Accordingly, the contact structure CS capable of electrically connecting the line of the front surface 100 and the line of the rear surface 200 may be manufactured.

The connection portion COS may be disposed in the hole structure to electrically connect the line of the front surface 100 and the line of the rear surface 200. For example, the connection portion COS may be cured after an ink including metal is supplied into the hole structure. In addition, the connection portion COS may be covered by the resin portion RES, and thus, may be protected.

According to an embodiment, after the current operation is performed, an inspection process for the display device DD may be performed. For example, the inspection process may be a process for determining whether the display layer DP normally emits light. For example, in order for the display layer DP to operate normally, an electric signal from the driving chip IC is required to be normally supplied to the display layer DP. At this time, the supplied electrical signal may be supplied to the display layer DP through the connection portion COS or a line in the folding area FA. According to an embodiment, the above-described inspection process may be performed before removing the folding area FA, and thus, the inspection process may be suitably performed with high reliability.

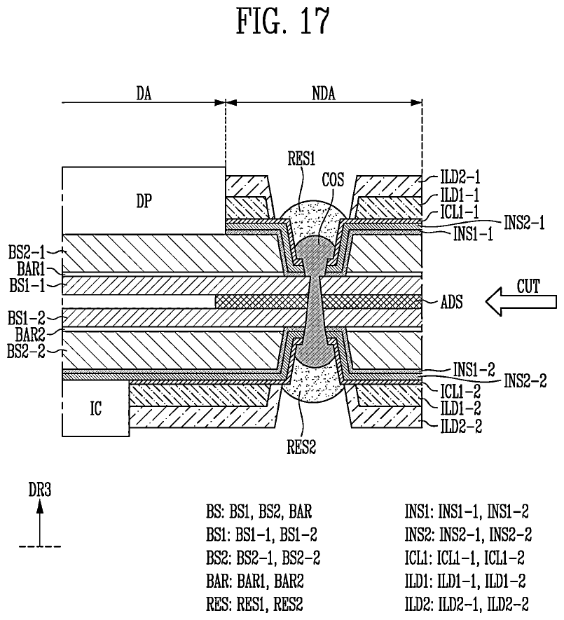

Referring to FIG. 17, stack structures in the folding area FA may be removed. Accordingly, some structures of side lines and the base layer BS may be removed. The structures in the folding area FA may be removed by a laser process or the like, but a removal method is not particularly limited in the disclosure.

Referring to a comparative example, when the side lines are formed, a concern that the non-display area NDA provided as the dead space may be excessively expanded exists. However, since the side lines are removed, and thus, a connection structure between the front surface 100 and the rear surface 200 according to an embodiment may be implemented by the contact structure CS, the dead space may be substantially reduced.

According to an embodiment, since the side lines may be removed from the display device DD, additional protection structures for protecting the side lines are not included. For example, when electrically connecting lines between the front surface 100 and the rear surface 200 using conventional side lines, structures for protecting the side lines are utilized, but such structures are not utilized according to an embodiment, and thus, a process cost may be substantially reduced.

In an embodiment, a cover resin layer or the like may be disposed to protect the non-display area NDA and at least a portion of a side surface thereof.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A display device, comprising:
a base layer including a first base layer including a first base hole, a second base layer including a second base hole, and a barrier layer disposed between the first base layer and the second base layer and including a barrier hole;
a display layer including a light emitting element;
a driving chip;
a first conductive layer including a (1-1)-th conductive layer electrically connected to at least a portion of the display layer and a (1-2)-th conductive layer electrically connected to the driving chip; and
a contact structure including a connection portion electrically connecting the (1-1)-th conductive layer and the (1-2)-th conductive layer,
wherein the first base layer includes a (1-1)-th base layer and a (1-2)-th base layer spaced apart in a thickness direction of the base layer, and the second base layer includes a (2-1)-th base layer and a (2-2)-th base layer spaced apart from each other in the thickness direction,
the barrier layer includes a first barrier layer and a second barrier layer spaced apart from each other in the thickness direction, the first barrier layer is disposed between the (1-1)-th base layer and the (2-1)-th base layer, and the second barrier layer is disposed between the (1-2)-th base layer and the (2-2)-th base layer,
the (2-1)-th base layer forms a front surface on which the display layer and the (1-1)-th conductive layer are disposed, and the (2-2)-th base layer forms a rear surface on which the driving chip and the (1-2)-th conductive layer are disposed, and
at least a portion of the connection portion is disposed in the first base hole, the first base hole is defined in each of the (1-1)-th base layer and the (1-2)-th base layer, and each of the (1-1)-th base layer and the (1-2)-th base layer includes a tapered surface on which the connection portion is disposed without including an under-cut structure in an area adjacent to the first base hole.

2. The display device of claim 1, wherein the first base layer includes a first organic material,
the barrier layer includes a first inorganic material, and
the second base layer includes a second organic material.

3. The display device according to claim 2, further comprising:
a first insulating layer disposed on the second base layer and including a first hole; and
a second insulating layer disposed on the first insulating layer and including a second hole,
wherein each of the first insulating layer and the second insulating layer includes a second inorganic material, and
the first hole, the second hole, the first base hole, and the second base hole are fluidly connected to each other.

4. The display device of claim 1, wherein the display layer includes a transistor electrically connected to the light emitting element and including a transistor electrode, and
the transistor electrode and the first conductive layer include a same material as each other.

5. The display device of claim 1, wherein in a plan view, a size of the second base hole and a size of the barrier hole correspond to each other.

6. The display device of claim 5, wherein an entirety of an upper surface of the barrier layer contacts a lower surface of the second base layer.

7. The display device of claim 1, wherein in a plan view, a size of the first base hole is smaller than a size of the barrier hole and a size of the second base hole.

8. The display device of claim 1, further comprising:
an adhesive layer disposed between the (1-1)-th base layer and the (1-2)-th base layer and including an adhesion hole,
wherein the first base hole and the adhesion hole have an hourglass shape in a cross-sectional view of the display device.

9. The display device of claim 1, further comprising:
an adhesive layer disposed between the (1-1)-th base layer and the (1-2)-th base layer and including an adhesion hole,
wherein the first base hole and the adhesion hole have a trapezoidal shape in a cross-sectional view of the display device.

10. The display device of claim 1, further comprising:
a first insulating layer disposed on the second base layer, including a first hole, and including an inorganic material,
wherein at least a portion of the barrier layer protrudes from the second base layer in a plan view, and
in the plan view, the first hole and the barrier hole have sizes corresponding to each other.

11. The display device of claim 1, wherein in a plan view, the first base hole and the barrier hole have sizes corresponding to each other.

12. The display device of claim 1, wherein the first base hole includes a first area where a first portion of the first base layer is removed by an etching process and a second area where a second portion of the first base layer is removed by a laser process, and
in a plan view, the first area removed by the etching process is greater than the second area removed by the laser process.

13. The display device of claim 1, further comprising:
a second conductive layer disposed on the first conductive layer,
wherein the second conductive layer is disposed on a same layer as at least a portion of a line of the display layer.

14. The display device of claim 1, wherein the contact structure is one of a plurality of contact structures arranged in a zigzag pattern.

15. A display device, comprising:
a display area and a non-display area;
a first base layer and a second base layer, each including an organic material;
a barrier layer having a first surface contacting the first base layer and a second surface contacting the second base layer, and including an inorganic material;
a light emitting element disposed on the second base layer in the display area; and
a contact structure formed in the non-display area and including a conductive connection portion,
wherein an entirety of the first surface of the barrier layer contacts the first base layer.

16. A method of manufacturing a display device, the method comprising:
manufacturing a base layer including a first base layer, a barrier layer, and a second base layer, and including a first area and a second area,
wherein a portion of the base layer in the first area overlaps another portion of the base layer in the second area;
exposing at least a portion of the first base layer in a hole formation area; and
forming a first base hole passing through the first base layer in the hole formation area after exposing the at least a portion of the first base layer in the hole formation area.

17. The method of claim 16, further comprising:
disposing a display layer in the first area on the second base layer and disposing a driving chip in the second area on the second base layer,
wherein the first base layer includes a (1-1)-th base layer disposed in the first area and a (1-2)-th base layer disposed in the second area, and the barrier layer includes a first barrier layer disposed in the first area and a second barrier layer disposed in the second area, and
the second base layer includes a (2-1)-th base layer disposed in the first area and a (2-2)-th base layer disposed in the second area.

18. The method of claim 17, further comprising:
folding the base layer; and
removing at least a portion of the folded base layer,
wherein folding the base layer comprises disposing the display layer on one side of the base layer in the first area and disposing the driving chip on another side of the base layer in the second area.

19. The method of claim 16, wherein forming the first base hole comprises removing at least a portion of the first base layer using a laser, and
when forming the first base hole, a layer including an inorganic material is not disposed in the hole formation area.

20. The method of claim 19, wherein the laser includes a first laser and a second laser directed toward different directions.
